(19) United States
(12) Patent Application Publication
(10) Pub. No.: US 2023/0042300 A1
(43) Pub. Date: Feb. 9, 2023

(54) ELECTRONIC DEVICE

(71) Applicant: Innolux Corporation, Miao-Li County (TW)

(72) Inventors: Neng-Jung You, Miao-Li County (TW); Yin-Jui Lu, Miao-Li County (TW); Tun-Huang Lin, Miao-Li County (TW); Hao-Jung Huang, Miao-Li County (TW); Ker-Yih Kao, Miao-Li County (TW)

(73) Assignee: Innolux Corporation, Miao-Li County (TW)

(21) Appl. No.: 17/860,089

(22) Filed: Jul. 7, 2022

Related U.S. Application Data
(60) Provisional application No. 63/229,510, filed on Aug. 5, 2021.

(30) Foreign Application Priority Data
Apr. 19, 2022 (CN) 202210411559.8

(51) Int. Cl. H01L 25/16; H01L 23/538; H01L 23/31

(52) U.S. Cl. CPC H01L 25/162; H01L 25/167; H01L 23/5385; H01L 23/3121; H01L 23/296

(57) ABSTRACT

The disclosure provides an electronic device including a substrate, a first semiconductor element, and a first protective structure. The first semiconductor element is disposed on the substrate and electrically connected to the substrate. The first semiconductor element has a first surface away from the substrate. The first protective structure covers at least a portion of the first surface.

### CROSS-REFERENCE TO RELATED APPLICATION

This application claims the priority benefits of U.S. provisional application Ser. No. 63/229,510, filed on Aug. 5, 2021, and China application serial no. 202210411559.8, filed on Apr. 19, 2022. The entirety of each of the above-mentioned patent applications is hereby incorporated by reference herein and made a part of this specification.

### BACKGROUND

### Technical Field

The disclosure relates to an electronic device, and more particularly, to an electronic device with better structural reliability.

### Description of Related Art

When a microelectronic element in the prior art (such as an integrated circuit or a light-emitting diode (micro LED), etc.) adopts glass as a carrier, and when the microelectronic element is cut, or the microelectronic element is bonded to a substrate (or circuit board), etc., the stress or impact etc., all may make the carrier or the circuit film layer thereon produce cracks at the cutting edges or corners, thereby affecting the quality and structural reliability of the product.

### SUMMARY

According to an embodiment of the disclosure, an electronic device includes a substrate, a first semiconductor element, and a first protective structure. The first semiconductor element is disposed on the substrate and electrically connected to the substrate. The first semiconductor element has a first surface away from the substrate. The first protective structure covers at least a portion of the first surface.

### BRIEF DESCRIPTION OF THE DRAWINGS

FIG. 1A is a schematic diagram of an electronic device of an embodiment of the disclosure.

FIG. 1B is a schematic top view of the first semiconductor element of the electronic device of FIG. 1A.

FIG. 1C is a schematic cross-sectional view along line I-I of FIG. 1B.

FIG. 2 is a schematic diagram of an electronic device of another embodiment of the disclosure.

FIG. 3 is a schematic cross-sectional view of a first semiconductor device of another embodiment of the disclosure.

FIG. 4A is a schematic side view of an electronic device of another embodiment of the disclosure.

FIG. 4B is a schematic top view of the electronic device of FIG. 4A.

FIG. 5 is a schematic diagram of an electronic device of another embodiment of the disclosure.

FIG. 6 is a schematic side view of an electronic device of another embodiment of the disclosure.

FIG. 7 is a schematic side view of an electronic device of another embodiment of the disclosure.

FIG. 8 is a schematic side view of an electronic device of another embodiment of the disclosure.

FIG. 9 is a schematic side view of an electronic device of another embodiment of the disclosure.

### DESCRIPTION OF THE EMBODIMENTS

An electronic device of an embodiment of the disclosure will be described in detail below. It should be appreciated that the following description provides many different embodiments for implementing various aspects of some embodiments of the disclosure. The specific elements and arrangements described below briefly and clearly describe some embodiments of the disclosure. Of course, these are examples and not limitations of the disclosure. Furthermore, similar and/or corresponding reference numerals may be used in different embodiments to designate similar and/or corresponding elements in order to clearly describe the disclosure. However, the use of these similar and/or corresponding reference numerals is for simplicity and clarity in describing some embodiments of the disclosure and does not imply any relationship between the different embodiments and/or structures discussed.

It should be understood that, relative terms, such as “lower” or “bottom” or “higher” or “top,” may be used in the embodiments to describe the relative relationship of one element of the drawings to another element. It will be understood that if the device in the figures were turned upside down, elements described on the “lower” side would become elements described on the “higher” side. The embodiments of the disclosure may be understood together with the drawings, and the drawings of the disclosure are also regarded as a part of the disclosure description. It should be understood that the drawings of the disclosure are not drawn to scale, and in fact, the dimensions of elements may be arbitrarily enlarged or reduced in order to clearly represent the features of the disclosure.

Moreover, when it is mentioned that a first material layer is located on or over a second material layer, the first material layer and the second material layer may be in direct contact or the first material layer and the second material layer may not be in direct contact. That is, one or more other material layers may be spaced between the first material layer and the second material layer. However, if the first material layer is directly located on the second material layer, it means that the first material layer and the second material layer are in direct contact.

Moreover, it should be noted that, the ordinal numbers used in the specification and claims, such as “first”, “second”, etc., are used to modify an element. They do not themselves imply and represent that the element(s) have any previous ordinal number, and also do not represent the order of one element and another element, or the order of manufacturing methods. The use of these ordinal numbers is to clearly distinguish an element with a certain name from another element with the same name. The same terms may be omitted in the claims and the specification. For example, the first element in the specification may be the second element in the claims.

In some embodiments of the disclosure, terms such as “connection”, “interconnection”, etc., regarding bonding and connection, unless specifically defined, may mean that two structures are in direct contact, or that two structures are not in direct contact and there are other structures located between these two structures. Moreover, the terms of bonding and connection may also include the case where both structures are movable or both structures are fixed. In addition, the terms “electrically connected” or “electrically coupled” include any direct and indirect electrical connection means.

In the specification, the terms “about” and “substantially” generally mean within 10%, or within 5%, or within 3%, or within 2%, or within 1%, or within 0.5% of a given value or range. Quantities given herein are approximate quantities, that is, in the absence of a specific description of “about” and “substantially”, the meanings of “about” and “substantially” may still be implied. The phrase “a range between a first numerical value and a second numerical value” means that the range includes the first numerical value, the second numerical value, and other numerical values in between. In addition, there may be a certain error in any two numerical values or directions for comparison. If the first numerical value is equal to the second numerical value, it implies that there may be an error of about 10% between the first numerical value and the second numerical value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms are used throughout the specification and the appended claims of the disclosure to refer to particular elements. Those skilled in the art should understand that electronic equipment manufacturers may refer to the same elements under different names. This specification is not intended to distinguish between elements having the same function but different names. In the following specification and claims, the words “including”, “containing”, “having” and the like are open words, so they should be interpreted as meaning “including but not limited to . . . ” Therefore, when the terms “including”, “containing”, and/or “having” are used in the description of the disclosure, they specify the presence of corresponding features, regions, steps, operations, and/or elements, but do not exclude the presence of one or more corresponding features, regions, steps, operations, and/or elements.

It should be noted that in the following embodiments, the features in several different embodiments may be replaced, recombined, and mixed to complete other embodiments without departing from the spirit of the disclosure. As long as the features between the embodiments do not violate the spirit of the disclosure or conflict with each other, they may be mixed and used arbitrarily.

Moreover, an electronic device disclosed in the disclosure may include a display device, a backlight device, an antenna device, a sensing device, a tiling device, a touch display device, a curved display, or a free shape display, but the disclosure is not limited thereto. The electronic device may include liquid crystal, light-emitting diode, fluorescence, phosphor, other suitable display medium, or a combination of the above, but the disclosure is not limited thereto. The display device may be a non-self-luminous type display device or a self-luminous type display device. The antenna device may be a liquid-crystal antenna device or a non-liquid-crystal antenna device, and the sensing device may be a sensing device sensing capacitance, light, heat, or ultrasound, but the disclosure is not limited thereto. The electronic element may include a passive element and an active element, such as a capacitor, a resistor, an inductor, a diode, a transistor, and so on. The diode may include a light-emitting diode (LED) or a photodiode. The light-emitting diode may include, for example, an organic light-emitting diode (OLED), a mini LED, a micro LED, or a quantum dot LED, but the disclosure is not limited thereto. The tiling device may be, for example, a display tiling device or an antenna tiling device, but the disclosure is not limited thereto. It should be noted that the electronic device may be any combination of the above, but the disclosure is not limited thereto. Moreover, the electronic device may be a bendable or flexible electronic device. It should be noted that the electronic device may be any combination of the above, but the disclosure is not limited thereto. In addition, the appearance of the electronic device may be rectangular, circular, polygonal, a shape with a curved edge, or other suitable shapes. The electronic device may have a peripheral system such as a driving system, a control system, a light source system, a shelf system, etc., to support a display device, an antenna device, or a tiling device. For the convenience of description, the following description will take the electronic device as the backlight device, but the disclosure is not limited thereto.

Unless otherwise defined, all terms (including technical and scientific terms) used herein have the same meaning as commonly understood by those skilled in the art to which the disclosure belongs. It should be understood that, these terms, such as those defined in commonly used dictionaries, should be interpreted as having meaning consistent with the relevant technique and the background or context of the disclosure, and should not be interpreted in an idealized or excessively formal manner, unless specifically defined in an embodiment of the disclosure.

Hereinafter, reference will be made in detail to exemplary embodiments of the disclosure, and examples of the exemplary embodiments are illustrated in the figures. Wherever possible, the same reference numerals are used in the figures and the descriptions to refer to the same or similar portions.

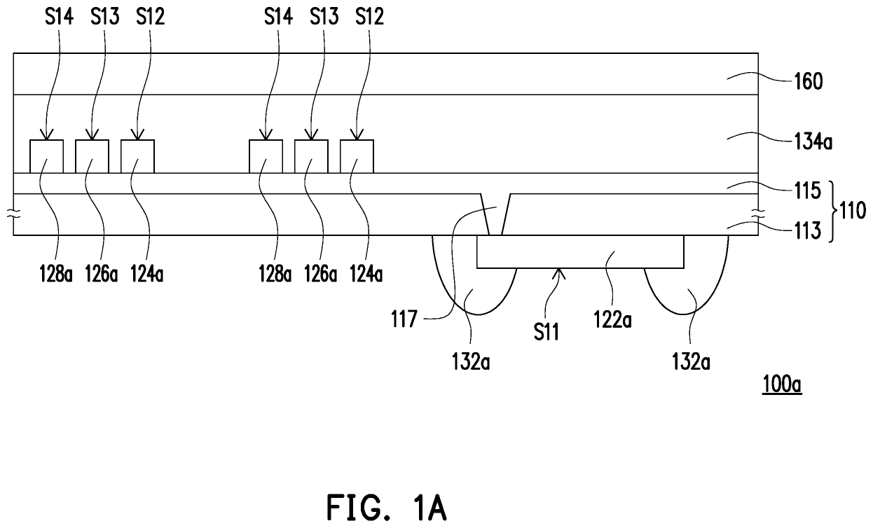

FIG. 1A is a schematic diagram of an electronic device of an embodiment of the disclosure. FIG. 1B is a schematic top view of the first semiconductor element of the electronic device of FIG. 1A. FIG. 1C is a schematic cross-sectional view along line I-I of FIG. 1B. For convenience of description, FIG. 1B is shown in a perspective manner, and some members are omitted.

Referring first to FIG. 1A, in the present embodiment, an electronic device 100a includes a substrate 110, a first semiconductor element 122a, a first semiconductor element 124a, and a first protective structure (e.g., a first protective structure 132a and a first protective structure 134a). The first semiconductor element 122a and the first semiconductor element 124a are disposed on the substrate 110 and electrically connected to the substrate 110. The first semiconductor element 122a has a first surface S11 away from the substrate 110, and the first semiconductor element 124a has a first surface S12 away from the substrate 110. A first protective structure 130a covers at least a portion of the first surface S11 and the first surface S12.

In some embodiments, the electronic device 100a is, for example, a backlight module, and the substrate 110 is, for example, a circuit board, but the disclosure is not limited thereto. In some embodiments, the substrate 110 may include a base 113 and a circuit layer 115, and the circuit layer 115 may be disposed on the base 113. In some embodiments, the first semiconductor element 122a and the first semiconductor element 124a may be located at two opposite sides of the substrate 110 respectively. That is, the first semiconductor element 122a and the first semiconductor element 124a are located at different sides of the substrate 110. The first semiconductor element 122a may be electrically connected to the circuit layer 115 via a conductive via 117 penetrating the base 113, but the disclosure is not limited thereto. The first semiconductor element 124a is disposed on the circuit layer 115 and electrically connected to the circuit layer 115. As shown in FIG. 1A and FIG. 1C, the first protective structure 132a may be disposed on a side of the substrate 110 adjacent to the first semiconductor element 122a, and the first protective structure 134a may be disposed on a side of the substrate 110 adjacent to the first semiconductor element 124a. In some embodiments, the first protective structure 134a may cover the first semiconductor element 124a. The material of the first protective structure (e.g., the first protective structure 132a and the first protective structure 134a) includes, for example, silicone, acrylic, urethane, or epoxy, and the first protective structure (e.g., the first protective structure 132a and the first protective structure 134a) may be provided as the first protective structure 130a by coating, jetting, dispensing, printing, or other suitable methods, but the disclosure is not limited thereto.

Please refer to FIG. 1B and FIG. 1C at the same time, the first semiconductor element 122a of the present embodiment may be, for example, an integrated circuit or a TFT circuit, the first semiconductor element 122a includes a carrier board 125a, and the material of the carrier board 125a may include, for example, glass, polyimide, other suitable materials, or a combination thereof, but the disclosure is not limited thereto. Moreover, the first semiconductor element 122a may include a chip body 127a and/or a buffer layer 129a, wherein the chip body 127a may be disposed on one side of the carrier board 125a, and the buffer layer 129a may be adjacent to or surround the chip body 127a. In some embodiments, the first semiconductor element 122a may include a plurality of pads 123a disposed between the buffer layer 129a (or the carrier board 125a) and the substrate 110, and the first semiconductor element 122a may be electrically connected to the substrate 110 via the pads 123a. The material of the pads 123a includes, for example, any suitable conductive material, such as tin, copper, and gold, but the disclosure is not limited thereto.

The electronic device 100a of the present embodiment further includes a material layer 140 disposed between the substrate 110 and the first semiconductor element 122a. The material layer 140 may be in contact with the first protective structure 132a. In some embodiments, the material layer 140 may be overlapped with the chip body 127a, and the material layer 140 may be used as a support member, for example, but the disclosure is not limited thereto. In other words, as shown in FIG. 1B, the orthographic projection of the material layer 140 on the substrate 110 is overlapped with the orthographic projection of the chip body 127a of the first semiconductor element 122a on the substrate 110. In some embodiments, the orthographic projection of the material layer 140 on the substrate 110 is not overlapped with the orthographic projection of the pads 123a on the substrate 110. In some embodiments, the pads 123a may surround the periphery of the material layer 140. In some embodiments, the material of the material layer 140 includes, for example, a non-conductive adhesive material, such as epoxy, but the disclosure is not limited thereto. The first protective structure 132a may be disposed between the substrate 110 and the first semiconductor element 122a. The electronic device 100a of the present embodiment may further include a partition structure 150 surrounding the first protective structure 132a. Here, the partition structure 150 may be used, for example, to limit the flow direction and/or the use amount of the first protective structure 132a. In some embodiments, the material of the partition structure 150 includes ink, but the disclosure is not limited thereto. In some embodiments, the first protective structure 132a includes, for example, an underfill, but the disclosure is not limited thereto.

Referring further to FIG. 1A, in the present embodiment, the electronic device 100a may further include a second semiconductor element 126a adjacent to the first semiconductor element 124a, the second semiconductor element 126a has a second surface S13 away from the substrate 110, and the first protective structure 130a may cover at least a portion of the second surface S13. The electronic device 100a of the present embodiment may further include a third semiconductor element 128a adjacent to the second semiconductor element 126a, the third semiconductor element 128a has a third surface S14 away from the substrate 110, and the first protective structure 130a covers at least a portion of the third surface S14. In some embodiments, the first protective structure 134a may, for example, cover the first semiconductor element 124a, the second semiconductor element 126a, and/or the third semiconductor element 128a. The first protective structure 134a includes, for example, a diffusion film, a diffusion adhesive, or a mold layer or an adhesive layer mixed with diffusion particles, but the disclosure is not limited thereto. In some embodiments, the first semiconductor element 124a, the second semiconductor element 126a, and/or the third semiconductor element 128a may be, for example, light-emitting diodes emitting light of the same color or light emitting-diodes emitting light of different colors respectively. In some embodiments, the first semiconductor element 124a, the second semiconductor element 126a, and/or the third semiconductor element 128a are disposed on the substrate 110 by, for example, chip (or bare chip) direct packaging (chip-on-board), but the disclosure is not limited thereto. In an embodiment, when the first semiconductor element 124a, the second semiconductor element 126a, and/or the third semiconductor element 128a are, for example, blue light-emitting diodes, green light-emitting diodes, and red light-emitting diodes, respectively, the three may be regarded as one light-emitting unit, but the disclosure is not limited thereto. In some embodiments, the first semiconductor elements 122a may control the first semiconductor element 124a, the second semiconductor element 126a, and/or the third semiconductor element 128a via the conductive via 117 and the circuit layer 115. In some embodiments, the first protective structure 134a may be used to improve light extraction effect. In some embodiments, the electronic device 100a may further include an optical film set 160 disposed on the first protective structure 134a to effectively increase the light extraction efficiency of the first semiconductor element 124a, the second semiconductor element 126a, and/or the third semiconductor element 128a.

Since the first protective structure 132a may cover at least a portion of the first surface S11 of the first semiconductor element 122a away from the substrate 110, and the first protective structure 134a may cover at least a portion of the first surface S12 of the first semiconductor element 124a away from the substrate 110, the expansion of cracks on the first semiconductor element 122a and the first semiconductor element 124a due to stress or impact during the cutting or bonding process may be effectively reduced. Alternatively, the first protective structure 132a and the first protective structure 134a may reduce water and oxygen erosion of the first semiconductor element 122a and/or the first semiconductor element 124a, so as to improve the quality of the first semiconductor element 122a and/or the first semiconductor element 124a. Similarly, the first protective structure 134a may further cover at least a portion of the second surface S13 of the second semiconductor element 126a away from the substrate 110, or may cover at least a portion of the third surface S14 of the third semiconductor element 128a away from the substrate 110, thereby achieving the advantages described above. In some embodiments, the first protective structure 132g may be located between the plurality of pads 123a of the first semiconductor element 122a.

It must be noted here that the following embodiments adopt the reference numerals and part of the content of the above embodiments, wherein the same reference numerals are used to represent the same or similar elements, and the description of the same technical content is omitted. For the description of the omitted parts, reference may be made to the above embodiment, which is not repeated in the following embodiments.

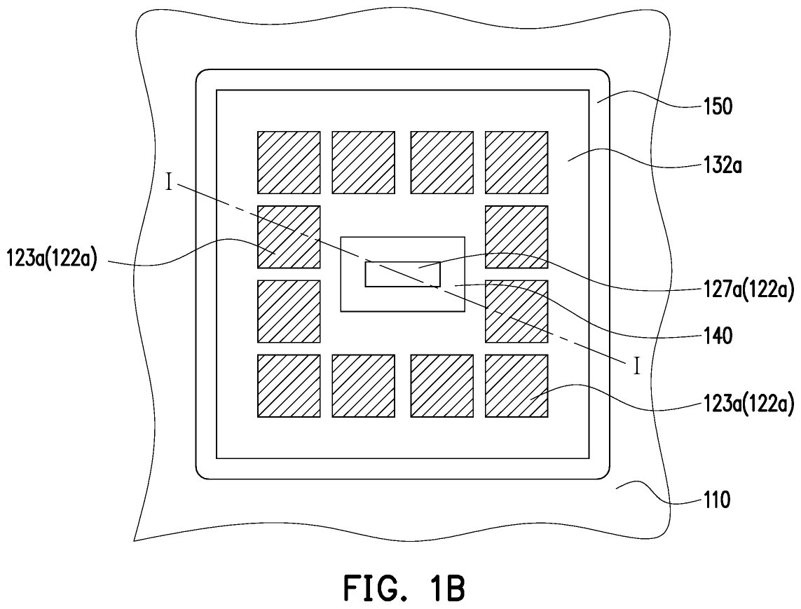

FIG. 2 is a schematic diagram of an electronic device of another embodiment of the disclosure. Please refer to FIG. 1A and FIG. 2 at the same time. In the present embodiment, an electronic device 100b is similar to the electronic device 100a of FIG. 1A. The difference between the two is that in the present embodiment, a first semiconductor element 122b, a first semiconductor element 124a, a second semiconductor element 126a, and a third semiconductor element 128a may all be located on the same side of the substrate 110, for example. The first semiconductor element 122b may control the first semiconductor element 124a, the second semiconductor element 126a, and/or the third semiconductor element 128a via the circuit layer 115. A first protective structure 130b covers at least a portion of a first surface S21 of the first semiconductor element 122b to effectively reduce the expansion of cracks on the first semiconductor element 122b caused by stress or impact during the cutting or bonding process, and at the same time may also reduce water and oxygen erosion of the first semiconductor element 122b. In addition, in some embodiments (as shown in FIG. 2), the first protective structure 134a in FIG. 1A may be optionally omitted or retained.

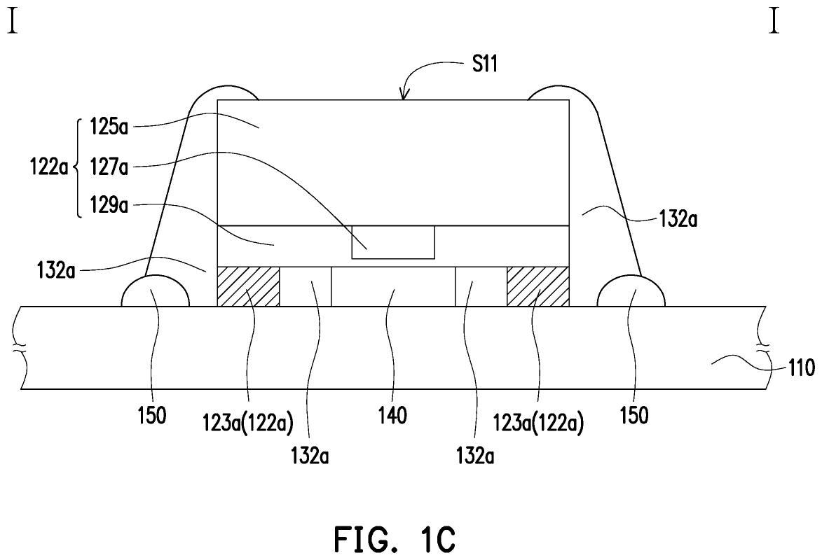

FIG. 3 is a schematic cross-sectional view of a first semiconductor device of another embodiment of the disclosure. Please refer to FIG. 1C and FIG. 3 at the same time. The difference between the two is that an electronic device 100c of the present embodiment does not have the partition structure 150 of FIG. 1C. A first protective structure 130c may be disposed between the substrate 110 and a first semiconductor element 122c. The first protective structure 130c may cover pads 123c, the material layer 140, the peripheral surface of a carrier board 125c, and/or the peripheral surface of a buffer layer 129c, and be extended to cover at least a portion of a first surface S31 to reduce the expansion of cracks on the first semiconductor element 122c due to stress or impact during the cutting or bonding process, and at the same time may also reduce the water and oxygen erosion of the first semiconductor element 122c.

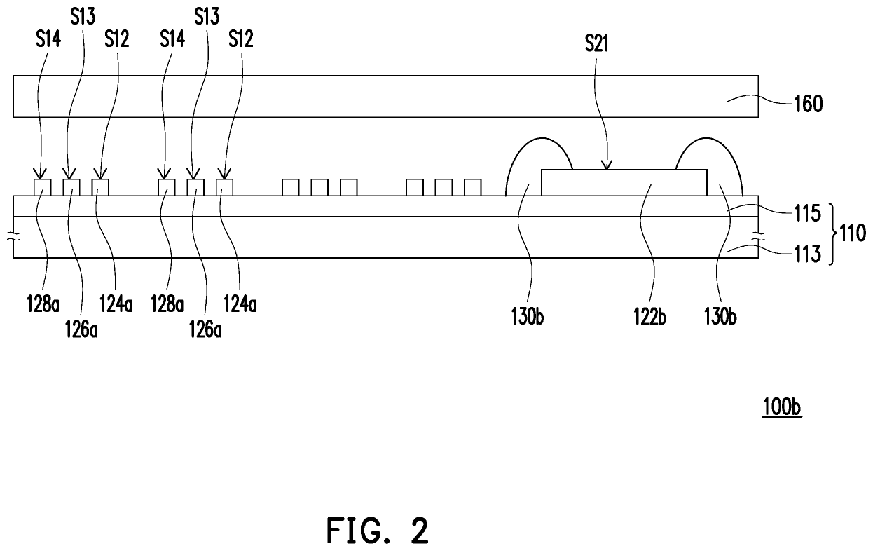

FIG. 4A is a schematic side view of an electronic device of another embodiment of the disclosure. FIG. 4B is a schematic top view of the electronic device of FIG. 4A. Please refer to FIG. 1A, FIG. 4A, and FIG. 4B at the same time. In the present embodiment, an electronic device 100d is similar to the electronic device 100a of FIG. 1A. The difference between the two is: in the present embodiment, a first semiconductor element 124d and a second semiconductor element 126d adjacent to the first semiconductor element 124d are electrically connected to the substrate 110 by a wire L. That is to say, the first semiconductor element 124d and the second semiconductor element 126d may be fixed to the substrate 110 by, for example, an attachment member (e.g., adhesive), and then electrically connected to the substrate 110 by the wire L. The first semiconductor element 124d and the second semiconductor element 126d may be, for example, integrated circuits or light-emitting diodes, and the material of the wire L may be, for example, gold or other suitable metal materials, but the disclosure is not limited thereto. A first protective structure 130d may cover at least a portion of a first surface S41 of the first semiconductor element 124d and/or a second surface S42 of the second semiconductor element 126d to reduce the expansion of cracks on the first semiconductor element 124d and the second semiconductor element 126d due to stress or impact during the cutting or bonding process or reduce the water and oxygen erosion of the first semiconductor element 124d and the second semiconductor element 126d. In an embodiment, in a first direction X (e.g., perpendicular to the normal direction of the substrate 110), the ratio of a width W1 of a portion of the first protective structure 130d on the first surface S41 to a width W2 of the first semiconductor element 124d may be, for example, 0.2 to 0.4 (i.e., 0.2≤W1/W2≤0.4), but the disclosure is not limited thereto.

In an embodiment, in the first direction X (e.g., perpendicular to the normal direction of the substrate 110), the ratio of a width W3 of a portion of the first protective structure 130d on the second surface S42 to a width W4 of the second semiconductor element 126d may be, for example, 0.2 to 0.4 (i.e., 0.2≤W3/W4≤0.4). Similarly, in an embodiment, in a first direction Y (e.g., perpendicular to the normal direction of the substrate 110), the ratio of a width W5 of a portion of the first protective structure 130d on the first surface S41 to a width W6 of the first semiconductor element 124d may be, for example, 0.2 to 0.4 (i.e., 0.2≤W5/W6≤0.4), but the disclosure is not limited thereto. In an embodiment, in the first direction Y (e.g., perpendicular to the normal direction of the substrate 110), the ratio of a width W7 of a portion of the first protective structure 130d on the second surface S42 to a width W8 of the second semiconductor element 126d may be, for example, 0.2 to 0.4 (i.e., 0.2≤W7/W8≤0.4).

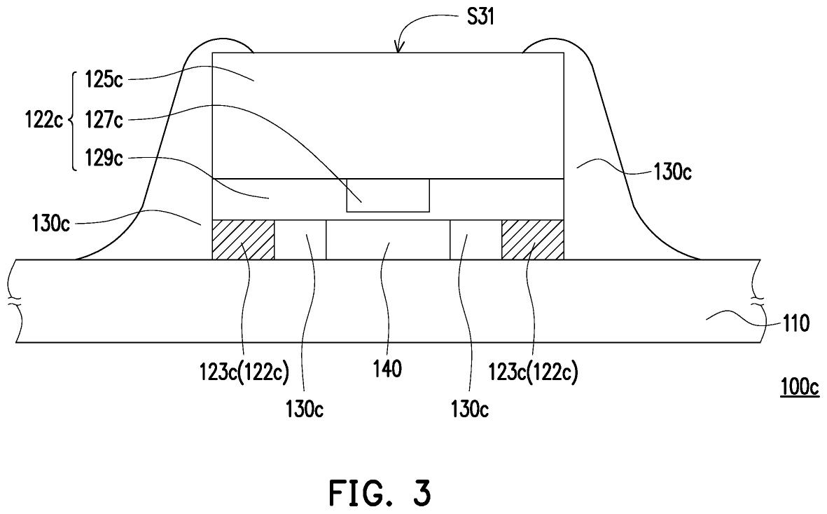

FIG. 5 is a schematic diagram of an electronic device of another embodiment of the disclosure. Please refer to FIG. 1A and FIG. 5 at the same time. In the present embodiment, an electronic device 100e is similar to the electronic device 100a of FIG. 1A, and the difference between the two is: the electronic device 100e of the present embodiment may be applied to, for example, a public information display (PID), but the disclosure is not limited thereto. The electronic device 100e may include a second protective structure 170e, and the second protective structure 170e may cover at least a portion of a first protective structure 130e. As shown in FIG. 5, a first semiconductor element 124e, a second semiconductor element 126e, and/or a third semiconductor element 128e may define one light-emitting unit, and FIG. 5 illustrates two light-emitting units, for example, but the disclosure is not limited thereto. The two light-emitting units may be respectively covered by the first protective structure 130e. That is, the first protective structure 130e may cover the first semiconductor element 124e, the second semiconductor element 126e, and the third semiconductor element 128e in each light-emitting unit, and the second protective structure 170e may cover a plurality of light-emitting units at the same time, for example, or may cover the first protective structures 130e of a plurality of light-emitting units at the same time and be in contact with a portion of the substrate 110. In an embodiment, a portion of the first protective structure 130e may be located between any two of the first semiconductor element 124e, the second semiconductor element 126e, and the third semiconductor element 128e. In an embodiment, a portion of the second protective structure 170e may be located between two adjacent first protective structures 130e. In an embodiment, the material of the first protective structure 130e and the material of the second protective structure 170e may include, for example, transparent silicone or epoxy, and the hardness of the second protective structure 170e may be, for example, greater than the hardness of the first protective structure 130e to prevent external stress, but the disclosure is not limited thereto.

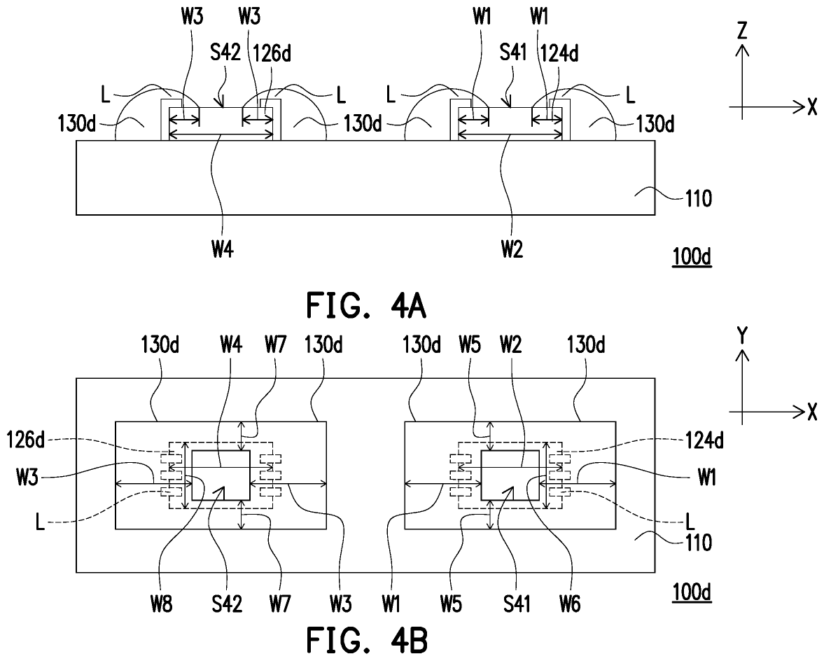

FIG. 6 is a schematic side view of an electronic device of another embodiment of the disclosure. Please refer to FIG. 1A and FIG. 6 at the same time, an electronic device 100f is similar to the electronic device 100a of FIG. 1A, and the difference between the two is: a first semiconductor element 124f and a second semiconductor element 126f are disposed on the substrate 110 in a flip-chip manner, for example. A first protective structure 130f may include a first protective layer 132f and a second protective layer 134f The first protective layer 130f may cover at least a portion of the side surface of the first semiconductor element 124f (or the second semiconductor element 126f), and the second protective layer 134f may cover the first protective layer 130f and a first surface S61 of the first semiconductor element 124f or a first surface S62 of the second semiconductor element 126f, respectively. The first protective layer 132f of the first protective structure 130f may be in contact with or cover at least a portion of the side surface and/or pads P of the first semiconductor element 124f, and the first protective layer 132f may be in contact with or cover at least a portion of the side surface of the second semiconductor element 126f and the pads P. In an embodiment, the first protective layer 132f may expose a portion of the side surface of the first semiconductor element 124f, or the first protective layer 132f may expose a portion of the side surface of the second semiconductor element 126f In an embodiment, the second protective layer 134f of the first protective structure 130f may cover the first protective layer 132f, the side surface of the first semiconductor element 124f exposed by the first protective layer 132f, and/or the first surface S61 of the first semiconductor element 124f The second protective layer 134f may cover the first protective layer 132f, the side surface of the second semiconductor element 126f exposed by the first protective layer 132f, and/or the second surface S62 of the second semiconductor element 126f. The first semiconductor element 124f and the second semiconductor element 126f may be respectively covered and protected by the first protective structure 130f Here, the first protective structure 130f may expose a portion of the upper surface 112 of the substrate 110. For example, the first protective layer 132f may be selected from a material with greater hardness, and the second protective layer 134f may be selected from a material with greater moisture or oxygen resistance, but the disclosure is not limited thereto.

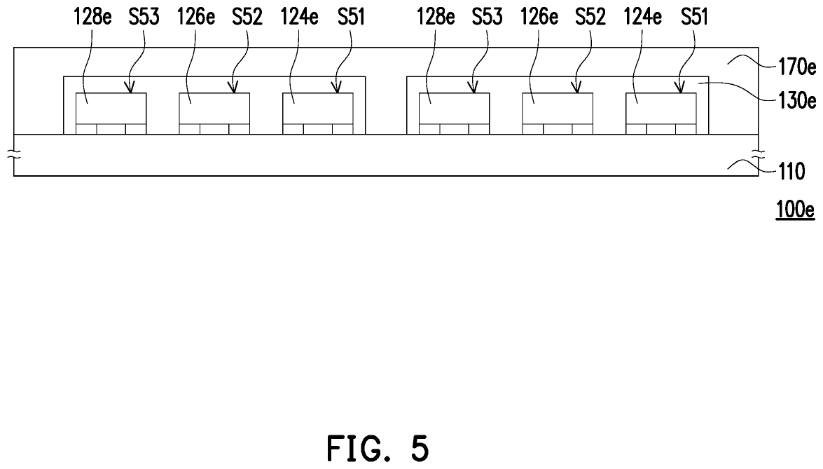

FIG. 7 is a schematic side view of an electronic device of another embodiment of the disclosure. Please refer to FIG. 1A and FIG. 7 at the same time. In the present embodiment, an electronic device 100g is similar to the electronic device 100f of FIG. 6, and the difference between the two is: a first semiconductor element 124g and a second semiconductor element 126g are electrically connected onto the substrate 110 by the wire L, for example. A first protective structure 130g of the electronic device 100g of the present embodiment may, for example, completely cover the side surface and an upper surface S71 of the first semiconductor element 124g. The first protective structure 130g may, for example, completely cover the side surface and an upper surface S72 of the second semiconductor element 126g. The first protective structure 130g may further cover the wire L.

Moreover, a second protective structure 170g covers at least a portion of the first protective structure 130g. Moreover, the first protective structure 130g and/or the second protective structure 170g may be in contact with a portion of the substrate 110, and the first protective structure 130g and/or the second protective structure 170g may expose a portion of the upper surface 112 of the substrate 110, but the disclosure is not limited thereto. That is, the first semiconductor element 124g and the second semiconductor element 126g may be covered and protected by the first protective structure 130g and the second protective structure 170g, respectively. Here, the first protective structure 130g may be made of a material with greater hardness, and the second protective structure 170g may be made of a material with high moisture resistance, but the disclosure is not limited thereto. In addition, the first protective structure 130g and/or the second protective structure 170g may have a curved upper surface.

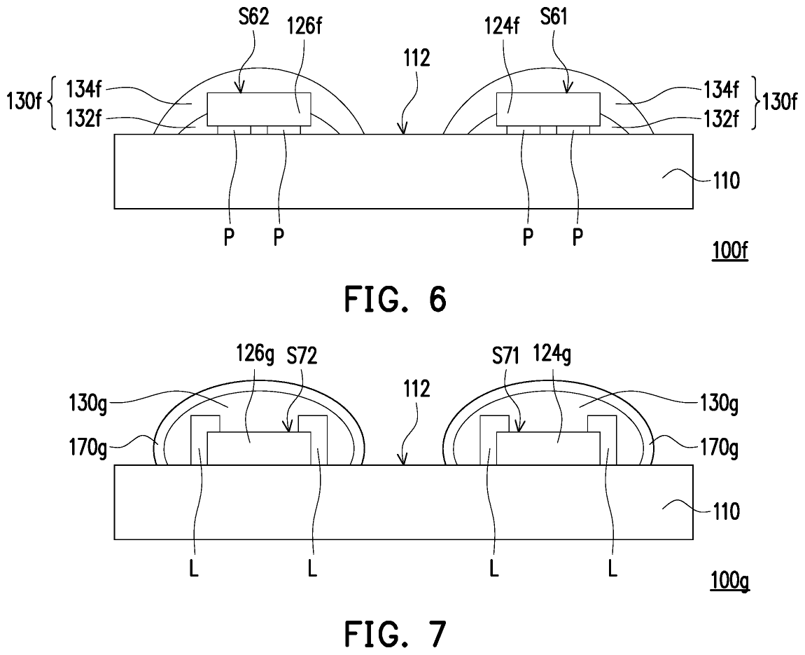

FIG. 8 is a schematic side view of an electronic device of another embodiment of the disclosure. Please refer to FIG. 1A and FIG. 8 at the same time. In the present embodiment, an electronic device 100h is similar to the electronic device 100a of FIG. 6, and the difference between the two is: a second protective layer 134h may cover a first semiconductor element 124h and a second semiconductor element 126h at the same time, but the disclosure is not limited thereto. That is, the second protective layer 134h may cover a plurality of semiconductor elements. In some embodiments, the second protective layer 134h in the first protective structure 130h may, for example, be substantially aligned with the side surface of the substrate 110. In other words, the second protective layer 134h in the first protective structure 130h may, for example, completely cover the upper surface of the substrate 110. Here, the first protective layer 132h may be made of a material with greater hardness, and the second protective layer 134h may be made of a material with high moisture resistance, but the disclosure is not limited thereto.

It should be noted that, when the first semiconductor element 124h and the second semiconductor element 126h are, for example, light-emitting diodes, the material of the second protective layer 134h may be selected from a material similar to a lens, and the upper surface of the second protective layer 134h may be, for example, substantially flat but may be designed with a slight microstructure (not shown), so as to improve the light extraction efficiency of the electronic device 100h. Furthermore, if the electronic device adopts a tiled electronic device 100h, the second protective layer 134h may, for example, substantially fill the tiling gap (not shown) of adjacent electronic devices, but the disclosure is not limited thereto. Moreover, when the first semiconductor element 124h and the second semiconductor element 126h are, for example, integrated circuits, due to no optical consideration, the shape of the first protective layer 132h may, for example, be substantially undulating along the shape of the first semiconductor element 124h and/or the second semiconductor element 126h, and the shape of the second protective layer 134h may, for example, be substantially undulating along the shape of the first protective layer 132h, but the disclosure is not limited thereto.

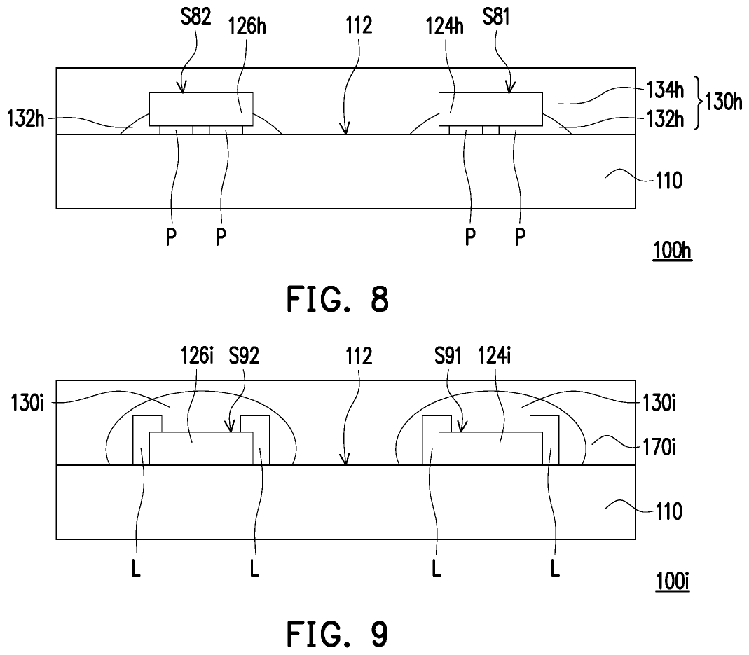

FIG. 9 is a schematic side view of an electronic device of another embodiment of the disclosure. Please refer to FIG. 1A and FIG. 9 at the same time. In the present embodiment, an electronic device 100i is similar to the electronic device 100g of FIG. 7, and the difference between the two is: a second protective structure 170i may cover a first protective structure 130i and the first protective structure 130i at the same time. In some embodiments, a first protective structure 170i may expose a portion of the upper surface 112 of the substrate 110, the second protective structure 170i may be disposed on the substrate 110, and the second protective structure 170i may cover the first protective structure 170i and a portion of the upper surface 112 of the substrate 110 exposed by the first protective structure 170i. In some embodiments, the second protective structure 170i may cover a plurality of semiconductor elements (e.g., a first semiconductor element 124i and a second semiconductor element 126i) at the same time. That is to say, the first semiconductor element 124i and the second semiconductor element 126i are respectively covered and protected by the first protective structure 130i, and the respective first protective structures 130i are simultaneously covered and protected by the second protective structure 170g. Here, the first protective structure 130i may be made of a material with greater hardness, and the second protective structure 170i may be made of a material with high moisture resistance, but the disclosure is not limited thereto.

Based on the above, in an embodiment of the disclosure, since the first protective structure covers at least a portion of the first surface of the first semiconductor element (or other semiconductor elements) away from the substrate, the expansion of cracks on the first semiconductor element (or other semiconductor elements) due to stress or impact during the cutting or bonding process may be effectively reduced. At the same time, the water and oxygen erosion of the first semiconductor element (or other semiconductor elements) may also be reduced, so that the electronic device of the disclosure has better structural reliability.

Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. An electronic device, comprising:
a substrate;
a first semiconductor element disposed on the substrate and electrically connected to the substrate, wherein the first semiconductor element has a first surface away from the substrate; and
a first protective structure covering at least a portion of the first surface.

2. The electronic device of claim 1, wherein the first semiconductor element comprises a carrier board, and a material of the carrier board comprises glass or polyimide.

3. The electronic device of claim 2, wherein the first semiconductor element further comprises a chip body and a buffer layer, the chip body may be disposed on one side of the carrier board, and the buffer layer is adjacent to or surrounds the chip body.

4. The electronic device of claim 1, wherein the first protective structure is disposed between the substrate and the first semiconductor element.

5. The electronic device of claim 4, further comprising:
a material layer disposed between the substrate and the first semiconductor element, and the material layer is in contact with the first protective structure.

6. The electronic device of claim 5, wherein an orthographic projection of the material layer on the substrate is overlapped with an orthographic projection of a chip body of the first semiconductor element on the substrate.

7. The electronic device of claim 5, wherein an orthographic projection of the material layer on the substrate is not overlapped with an orthographic projection of a pad of the first semiconductor element on the substrate.

8. The electronic device of claim 1, further comprising:
a second protective structure covering at least a portion of the first protective structure.

9. The electronic device of claim 8, wherein the second protective structure is in contact with the substrate.

10. The electronic device of claim 8, wherein a hardness of the second protective structure is greater than a hardness of the first protective structure.

11. The electronic device of claim 1, further comprising:
a second semiconductor element adjacent to the first semiconductor element, wherein the second semiconductor element has a second surface away from the substrate, and the first protective structure covers at least a portion of the second surface.

12. The electronic device of claim 11, further comprising:
a second protective structure disposed on the substrate, wherein the first protective structure exposes a portion of an upper surface of the substrate, and the second protective structure covers the first protective structure and the portion of the upper surface of the substrate exposed by the first protective structure.

13. The electronic device of claim 1, wherein the first protective structure comprises a first protective layer and a second protective layer, the first protective layer covers at least a portion of a side surface of the first semiconductor element, and the second protective layer covers the first protective layer and the first surface of the first semiconductor element.

14. The electronic device of claim 1, further comprising:
a partition structure surrounding the first protective structure.

15. The electronic device of claim 1, wherein the substrate comprises a base, a circuit layer, and a conductive via, and the first semiconductor element is electrically connected to the circuit layer via the conductive via penetrating the base.

16. The electronic device of claim 1, wherein the substrate comprises a base and a circuit layer, the circuit layer is disposed on the base, and the first semiconductor element is disposed on the circuit layer and electrically connected to the circuit layer.

17. The electronic device of claim 1, wherein a material of the first protective structure comprises, for example, silicone, acrylic, urethane, or epoxy.

18. The electronic device of claim 1, wherein the first protective structure comprises a diffusion film, a diffusion adhesive, or a mold layer or an adhesive layer mixed with diffusion particles.

19. The electronic device of claim 18, further comprising:
an optical film set disposed on the first protective structure.

20. The electronic device of claim 1, wherein in a first direction, a ratio of a width of a portion of the first protective structure on the first surface to a width of the first semiconductor element is 0.2 to 0.4.
